(19) United States
(12) Patent Application Publication
(10) Pub. No.: US 2007/0201203 A1
(43) Pub. Date: Aug. 30, 2007

(54) Adhesion Material Structure and Process Method Thereof

(76) Inventors: Ming-Hang Hwang, Taipei City (TW); Yu-Chiang Cheng, Taipei City (TW); Chao-Yi Chen, Taipei City (TW); Hsin-Lung Kuo, Taipei City (TW); Bin-Wei Lee, Taipei City (TW); Wei-Chung Hsiao, Taipei City (TW)

Correspondence Address: LAW OFFICES OF LAI AND ASSOCIATES, P.C., 5800 RANCHESTER STE 200, HOUSTON, TX, 77036, US

(21) Appl. No.: 11/307,847

(22) Filed: Feb. 24, 2006

(51) Int. Cl. H05K 7/20

(52) U.S. Cl. 361/688

(57) ABSTRACT

This invention discloses a process method and structure for an adhesion material. The adhesion material is employed for a heat dissipation device that includes several heat sink fins, a heat dissipation slip and a heat pipe. The heat pipe connects several heat sink fins and a heat dissipation slip by the adhesion material. The metal is combed with a bracket structure of carbon element, which has high thermal conductivity, so as to improve the heat conduction efficiency; the adhesion material can be made. The corresponding process method for the adhesion material can be made with a mode of process to form melting stuff, including the metal and a bracket structure of carbon element, and then uses a mode of draw to form the adhesion material. The bracket structure of carbon element can be mixed into the metal.

### FIELD OF THE INVENTION

The present invention relates to an adhesion material structure and a process method and, more particularly, to a method for manufacturing the adhesion material which combines a metal with a bracket structure of carbon element.

### BACKGROUND OF THE INVENTION

In recent years, the pace of high technology industry development is extremely fast, the development of electronic components is toward small volumes and high densities. Relatively, much waste heat is generated and is unavoidable. The performance of the electronic components will be decreased if the waste heat is unable to eliminate appropriately. Therefore, various heat conduction materials are provided to improve the efficiency of heat dissipation.

Each heat dissipation component needs to be connected together to improve the efficiency of heat dissipation after a heat dissipation slip, a heat sink fin and a heat pipe are provided one by one. The connection technique usually uses welding that two components are combined together by using a melted metal.

A conventional arc welding is that current passes a weldment through an electrode to generate high temperature immediately. A crater is melted and is then cooled to weld two components. Referring to FIG. 1, a schematic diagram illustrates a conventional arc welding. The arc welding comprises a welding machine 11, an electrode fixture 12, an electrode 13, a weldment 14, a ground wire 15 and an electrode lead 16. The welding machine 11 is connected to the electrode fixture 12 via the electrode lead 16 and the ground wire 15 is connected to the weldment 14. The electrode 13 is clipped by the electrode fixture 12. Currents provided by the welding machine 11 pass through the electrode lead 16 and reaches the electrode 13 clipped by the electrode fixture 12. Electrons jump between an end of the electrode 13 and the weldment 14 to generate arcs 17 and the remaining currents then return to the welding machine 11 through the ground wire 15 which is connected to the weldment 14. Above procedure is a current loop of the arc welding. The jump pitch may generate higher impedance for the electron current and the arcs 17 are then generated. The electrode 13 is melted through the arcs 17 and the melted particles are dripped on the weldment 14 for welding. The metallic characteristics of the electrode may be changed when the electrode experiences melting, adhering and cooling and then the metal existed between the weldment may cause the thermal resistance for thermal conduction.

Besides, diamonds are well known and have characteristics with the highest hardness, the fastest heat conduction, and the widest refraction range. Diamonds, therefore, are always one of more important materials in engineering due to the excellent characteristics. The thermal conductivity of diamonds at the normal atmospheric temperature is five times more than copper. Moreover, the thermal expansion factor of diamonds at high temperature is very small that shows the excellent efficiency of heat dissipation. The feature may help people to differentiate the adulteration of diamonds. In the prior art, many technologies and manufacture methods have been developed to make diamonds. The direct decomposition for hydrocarbons is the most familiar method like Microwave Plasma Enhance Chemical Vapor Deposition (MPCVD) and Hot Filament CVD (HFCVD). By the aforesaid methods, polycrystalline diamond films can be deposited. The characteristic of the polycrystalline diamond films is same as the single crystal diamonds.

Accordingly, an adhesion material and corresponding manufacturing process are provided to satisfy the demand of thermal conduction and the welding technique simultaneously.

### SUMMARY OF THE INVENTION

The inventor of the present invention based on years of experience on related research and development of the heat dissipation device welding to invent an adhesion material and manufacturing method to overcome the foregoing shortcomings.

The object of the present invention is to provide an adhesion material and manufacturing process applying for a heat dissipation device. The adhesion material combines a metal with a bracket structure of carbon element. The metal can be copper, aluminum, tin or a metal material with high thermal conductivity. The bracket structure of carbon element is diamonds. The adhesion material is made by a manufacturing process to form a melt material having a metal and a bracket structure of carbon element. The melt material is made by a melt way or a drawing process, wherein the adhesion material comprises the melt material.

Other features and advantages of the present invention and variations thereof will become apparent from the following description, drawings, and claims.

### BRIEF DESCRIPTION OF THE DRAWINGS

FIG. 1 is a schematic diagram illustrating a conventional arc welding;

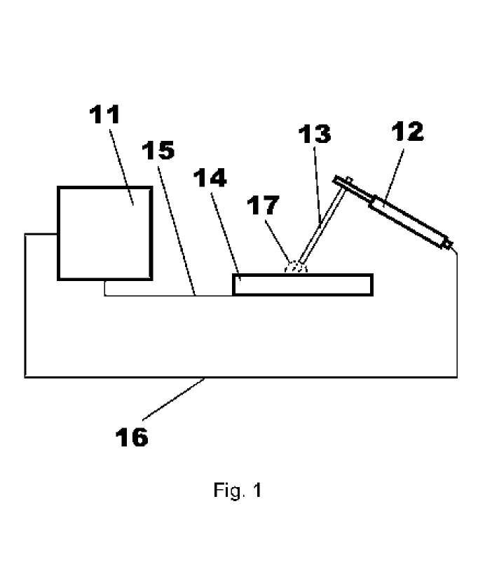

FIG. 2 is a schematic diagram illustrating an adhesion material applying for a heat dissipation device according to a preferred embodiment of the present invention;

FIG. 3 is a schematic diagram illustrating a manufacturing process for making the adhesion material according to an embodiment of the present invention;

FIG. 4 is a schematic diagram illustrating a drawing process for making the adhesion material according to an embodiment of the present invention; and

FIG. 5 is a flowchart illustrating a manufacturing process for making the adhesion material according to an embodiment of the present invention.

### DETAILED DESCRIPTION OF THE PREFERRED EMBODIMENTS

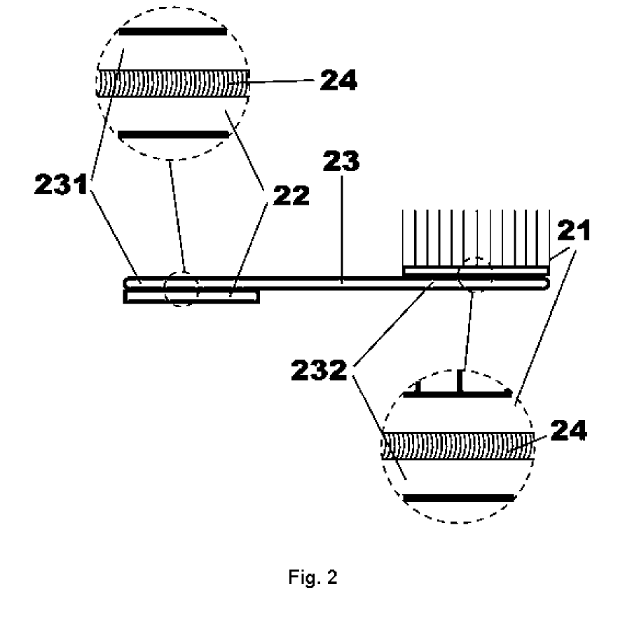

Referring to FIG. 2, a schematic diagram illustrates an adhesion material applying for a heat dissipation device according to a preferred embodiment of the present invention. In the embodiment, the heat dissipation device comprises a plurality of heat sink fins 21, a heat dissipation slip 22 and a heat pipe 23. The heat pipe 23 has a first connection end 231 and a second connection end 232. The second connection end 232 is connected to the plurality of heat sink fins 21 and the first connection end 231 is connected to the heat dissipation slip 22. The adhesion material 24 is used to at least an adhesion location and the adhesion material 24 combines a metal and a bracket structure of carbon element. The metal can be copper, aluminum, tin or a metal material with high thermal conductivity. The bracket structure of carbon element is diamonds.

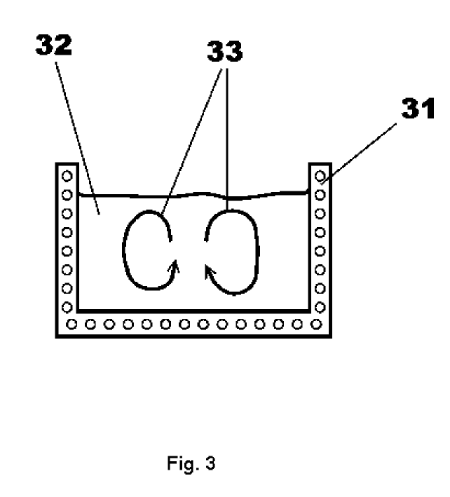

Referring to FIG. 3, a schematic diagram illustrates a manufacturing process for making the adhesion material according to an embodiment of the present invention. The manufacturing comprises a high temperature furnace 31 and a material combining a metal with a bracket structure of carbon element. The metal is filled into the high temperature furnace 31 and the metal is then melted down. The bracket structure of carbon element is mixed into the melted metal to form a melt material 32. In another word, the mixing is that the bracket structure of carbon element is uniformly mixed into the melted metal through a convection 33 caused by temperature gradient of the melted metal within the high temperature furnace 31 Copper, aluminum, tin or a metal material with high thermal conductivity is provided to be the metal and diamonds are provided to be the bracket structure of carbon element.

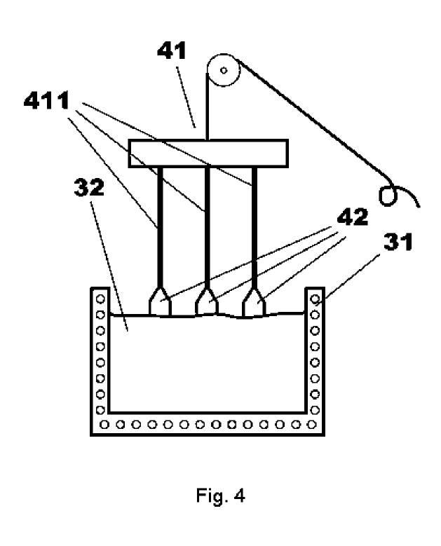

The melt material is then formed to an adhesion material by employing a drawing process as shown in FIG. 4. In the embodiment, the drawing process comprises a drawing apparatus 41, the high temperature furnace 31 and the melt material 32. The drawing apparatus 41 comprises a plurality of drawing units 411 for drawing the melt material 32 from the high temperature furnace 31 to form an adhesion material 42 with columnar. The adhesion material 42 is acquired by the drawing apparatus 41 via ascending velocity of controlling the plurality of drawing units 411.

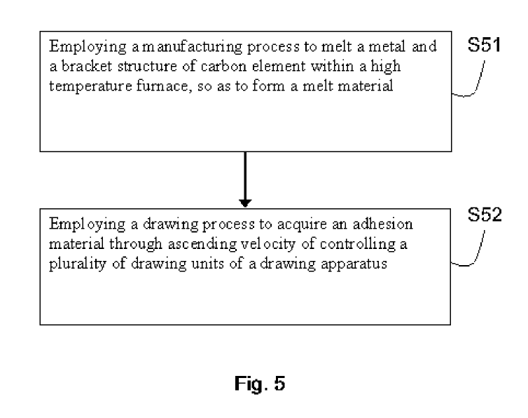

Referring to FIG. 5, a flowchart illustrates a manufacturing process for making the adhesion material according to an embodiment of the present invention. The process comprises the steps as follows: Step S51, employing a manufacturing process to melt a metal and a bracket structure of carbon element within a high temperature furnace, so as to form a melt material; step S52, employing a drawing process to acquire an adhesion material through ascending velocity of controlling a plurality of drawing units of a drawing apparatus.

Therefore, the thermal resistance of thermal conduction caused by the changes of metallic characteristics can be improved by providing an adhesion material combining a metal with a bracket structure of carbon element and corresponding manufacturing process.

Although the features and advantages of the embodiments according to the preferred invention are disclosed, it is not limited to the embodiments described above, but encompasses any and all modifications and changes within the spirit and scope of the following claims.

What is claimed is:

1. An adhesion material, applied for a heat dissipation device, said heat dissipation device comprising a plurality of heat sink fins, a heat dissipation slip and a heat pipe, a first connection end of said heat pipe being connected to said heat sink fins and a second connection end of said heat pipe being connected to said heat dissipation slip; wherein the characterized in that:
said adhesion material is used for at least a adhesion location of said heat dissipation device, said adhesion material is combined a metal with a bracket structure of carbon element.

2. The adhesion material of claim 1, wherein said at least an adhesion location is formed to said first connection end.

3. The adhesion material of claim 1, wherein said at least an adhesion location is formed to said second connection end.

4. The adhesion material of claim 1, wherein said metal is copper.

5. The adhesion material of claim 1, wherein said metal is aluminum.

6. The adhesion material of claim 1, wherein said metal is tin.

7. The adhesion material of claim 1, wherein said metal is a metal material with high thermal conductivity.

8. The adhesion material of claim 1, wherein said bracket structure of carbon element is diamonds.

9. A method for manufacturing an adhesion material, comprising:
employing a manufacture process to form a melt material having a metal and a bracket structure of carbon element;
employing a drawing process to form said adhesion material, wherein said adhesion material comprises said melt material.

10. The method for manufacturing an adhesion material of claim 9, wherein said melt material is formed by a melt way.

11. The method for manufacturing an adhesion material of claim 9, wherein said metal is copper.

12. The method for manufacturing an adhesion material of claim 9, wherein said metal is aluminum.

13. The method for manufacturing an adhesion material of claim 9, wherein said metal is tin.

14. The method for manufacturing an adhesion material of claim 9, wherein said metal is a metal material with high thermal conductivity.

15. The method for manufacturing an adhesion material of claim 9, wherein said bracket structure of carbon element is diamonds.
